(19) United States
(12) Patent Application Publication
(10) Pub. No.: US 2026/0178794 A1
(43) Pub. Date: Jun. 25, 2026

(54) DERIVATION OF AN ELECTROMAGNETIC SPECTRUM FROM A MULTI-STIMULUS COLOR VALUE FOR SIMULATING A CAMERA

(71) Applicant: dSPACE GmbH, Paderborn (DE)

(72) Inventors: Christoph Brodehl, Paderborn (DE); Stefan Hante, Paderborn (DE)

(21) Appl. No.: 19/241,473

(22) Filed: Jun. 18, 2025

(30) Foreign Application Priority Data
Dec. 20, 2024 (DE) 102024139225.8

(51) Int. Cl. G06F 30/20; G06T 7/90

(52) U.S. Cl. CPC G06F 30/20; G06T 7/90

(57) ABSTRACT

A method for generating synthetic camera data includes: rendering an image of a virtual scene and storing color information of a surface element of the virtual scene; assigning, to the surface element, a number of base functions which each describe a relative wavelength distribution of a light component emitted from the surface element; modeling a spectral radiance of the light emitted from the surface element as a linear combination of the base functions; deriving the scaling factors of the base functions in the linear combination by arithmetically combining the spectral radiance with a color space coordinate from the color information of the surface element and a color matching function associated with the color space coordinate; calculating the spectral radiance by inserting the scaling factors; and generating the synthetic camera data by processing the spectral radiance in a camera simulation of a camera located in the virtual scene.

### CROSS-REFERENCE TO PRIOR APPLICATIONS

This application claims benefit to German Patent Application No. DE 102024139225.8, filed on Dec. 20, 2024, which is hereby incorporated by reference herein.

### BACKGROUND

Cameras are increasingly used in intelligent automated systems that are able to derive a detailed picture of their environment based on a camera image and to autonomously react to occurrences in the environment. Examples of such systems are highly automated to autonomous vehicles or robots that can move independently and safely in an unknown environment. Another example is surveillance systems that can independently detect dangerous or unwanted situations in a camera image and issue an alarm.

Such camera-based systems often perform safety-critical tasks and require thorough evaluation before they are mass-produced. Evaluation in a real-world environment is usually time-consuming because critical events naturally occur rarely and are not reproducible. It is therefore common practice to perform test runs of the system at least partly in a virtual environment in which the camera data is synthesized based on the virtual environment and provided to the system under test.

If the camera-based system is based on trained artificial intelligence (AI), for example, an AI for object detection, face recognition, or scene interpretation, there is an analog problem for the training of the AI. Certain training situations may be rare and not reproducible. This is why there are increasing efforts to train AIs in virtual environments using synthetic camera data.

It is important for both evaluation and training of camera-based systems that the synthetic camera data is plausible, i.e., that it is as similar as possible to real camera data, so that the results obtained on the basis of the synthetic camera data in the virtual environment can be transferred to the real world. For this purpose, it may be necessary to realistically simulate the technical/physical processes in the camera that are gone through to generate the camera data in a real camera, especially if the synthetic camera data is intended to imitate camera data with a low level of processing, e.g., the raw camera data generated by the image sensor.

The light emitted by the real environment and illuminating a real camera image sensor is spectral. It is composed of a continuous spectrum of different wavelengths. Typical graphics engines for rendering virtual environments (e.g., Unreal Engine, Unity Engine, CryEngine) represent color as mixtures of a small number of discrete color values, typically using an RGB color space. These are tristimulus color spaces that represent each color shade as a mixture of three discrete color components: red, green, and blue. Although this representation allows a realistic color perception in the human eye, it does not correspond to the physical reality. A camera simulation fed with RGB color values does not generate camera raw data corresponding to reality, even under the assumption of a perfect simulation of the image sensor and of the imaging optics.

In the prior art, it is known to use what is called spectral rendering for computer-implemented simulation of wave-optical phenomena, in particular the exposure and image data generation of a digital camera. In this technique, color is a priori not modeled as a discrete multi-stimulus color value, but as a spectrum. Examples include the scientific paper entitled “Digital Camera Simulation” by Joyce Farrel, Peter Catrysse, and Bran Wandell (Applied Optics 51(4), 2012) and the patent publication U.S. Pat. No. 5,710,876 A. However, experience has shown that the computing effort required for this is so high that real-time camera simulation with sufficient quality is not possible.

To reduce the computational effort, it is known to estimate a spectrum from a given RGB value and thus use an already existing native RGB pipeline for spectral light simulation.

Such an approach is disclosed, for example, in the scientific paper entitled “GPU Rendering of the Thin Film on Paints with Full Spectrum” by Roman Ďurikovič and Ryou Kimura (Tenth International Conference on Information Visualization, 2006). The paper proposes to replace the given RGB values with a linear combination of three predetermined spectra that are perceived in the human eye as red, green, and blue, respectively. While this method can be performed quickly, it is a rather rough approximation and is not suitable for simulating infrared or ultraviolet cameras, which operate outside the visible spectrum.

Also known to those skilled in the art are various methods for calculating synthetic camera data based on a camera simulation and a virtual scenery. An introduction can be found, for example, in the publication entitled “Full Spectrum Camera Simulation for Reliable Virtual Development and Validation of ADAS and Automated Driving Application” by René Molenaar et al. (IEEE Intelligent Vehicles Symposium (IV), 2015).

### SUMMARY

In an exemplary embodiment, the present invention provides a method for generating synthetic camera data. The method includes: rendering, by a computer system, an image of a virtual scene and storing color information of a surface element of the virtual scene in the form of color space coordinates of a multi-stimulus color space; assigning, by the computer system, to the surface element, a number of base functions which each describe a relative wavelength distribution of a light component emitted from the surface element; modeling, by the computer system, a spectral radiance of the light emitted from the surface element as a linear combination of the base functions; deriving, by the computer system, the scaling factors of the base functions in the linear combination by arithmetically combining the spectral radiance with a color space coordinate from the color information of the surface element and a color matching function associated with the color space coordinate; calculating, by the computer system, the spectral radiance by inserting the scaling factors; and generating, by the computer system, the synthetic camera data by processing the spectral radiance in a camera simulation of a camera located in the virtual scene.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a data pipeline for generating the camera data;

FIG. 2 shows the angle-dependent generation of multi-stimulus image data; and

FIG. 3 shows an example of a virtual scenario.

### DETAILED DESCRIPTION

Exemplary embodiments of the invention improve upon rapid estimation of a spectrum from a given multi-stimulus color value.

In an exemplary embodiment, the present invention provides a computer-implemented method for generating synthetic camera data. The method includes rendering an image of a virtual scenery and storing color information of at least one surface element of the virtual scenery in the form of color space coordinates of a multi-stimulus color space. A surface element may be, for example, a polygon, a surfel, a texture, a pixel, or a side face of a voxel. A multi-stimulus color space is understood to be a color space that models colors as N-dimensional vectors or value tuples, with each vector coordinate representing a discrete, predetermined color value. Computer graphics, especially those of commonly used graphics engines, are mostly based on a three-dimensional RGB color space, such as the sRGB color space.

The light emitted from the surface element is initially modeled as a linear combination of a number of m base functions B according to the formula

$$L ( λ ) = {c}_{1} {B}_{1} ( λ ) + … + {c}_{m} {B}_{m} ( λ ) \qquad ( 1 )$$

where L is a spectral radiance of the surface element, and each base function is a relative wavelength distribution of a light component emitted from the surface element. The spectral radiance is thus described as a superposition of m electromagnetic spectra with scaling factors c₁, . . . , cₘ still to be determined.

The scaling factors of the linear combination are derived by arithmetically combining the spectral radiance with at least one color space coordinate from the color information of the surface element and at least one color matching function associated with the color space coordinate. The following formula can be used for each color space coordinate:

$${k}_{i} = {R}_{i} {\int }_{{λ}_{1}}^{{λ}_{2}} L ( λ ) {\overline{k}}_{ι} ( λ ) d λ \qquad ( 2 )$$

where kᵢ is a coordinate of the color space vector k=(k₁, k₂, . . . , kₙ). In the sRGB color space, for example, the following holds: k=(r, g, b). The vector k̅ (k̅₁, k̅₂, . . . , k̅ₙ) contains the color matching functions associated with the color space coordinates. In the sRGB color space, k̅=(r̅, g̅, b̅) are linear transformations of the CIE 1931 RGB color matching functions. Rᵢ=(R₁, R₂, . . . , Rₙ) are color-space-specific constants. Formula (2) is usually used to assign a set of color space coordinates k to a given electromagnetic spectrum, described by the spectral radiance L, which color space coordinates produce the same color perception as the given spectrum in the human eye. In a method according to an embodiment of the invention, the color space coordinates of the surface element are already known. Inserting equation (1) into equation (2) yields the system of equations

$${k}_{1} = {c}_{1} {R}_{1} {\int }_{{λ}_{1}}^{{λ}_{2}} {B}_{1} ( λ ) {\overline{k}}_{1} dλ + … + {c}_{m} {R}_{1} {\int }_{{λ}_{1}}^{{λ}_{2}} {B}_{m} ( λ ) {\overline{k}}_{1} ( λ ) d λ \qquad ( 3 )$$

$$⋮$$

$${k}_{n} = {C}_{1} {R}_{n} {\int }_{{λ}_{1}}^{{λ}_{2}} {B}_{1} ( λ ) {\overline{k}}_{n} ( λ ) dλ + … + {c}_{m} {R}_{n} {\int }_{{λ}_{1}}^{{λ}_{2}} {B}_{m} ( λ ) {\overline{k}}_{n} ( λ ) d λ$$

for determining the scaling factors c₁, . . . , cₘ. Inserting the scaling factors c₁, . . . , cₘ into equation (1) yields the spectral radiance of the surface element.

The synthetic camera data is calculated by processing the spectral radiance in a correspondingly designed camera simulation of a camera located in the virtual scenery.

To derive an electromagnetic spectrum, the method arithmetically combines a physically plausible presumption about the radiation spectrum of a surface element (equation 1) with the predefined multi-stimulus color values of the surface element from the virtual scenery. The spectrum derived in this way is more realistic than in the prior art methods and therefore produces qualitatively better synthetic camera data, but it can also be performed sufficiently quickly for a camera simulation in real time. Such simulation is useful if the synthetic camera data is intended for stimulating a test object in the form of standalone hardware located outside of the computer system that is used to generate the synthetic camera data in accordance with aspects of the invention (“hardware in the loop”). Such a test object expects to receive current camera data within specified time intervals. Accordingly, the method calculates and provides such data within the same time intervals. The repetition of the method steps is then advantageously linked to a scene simulation that simulates an evolution of the virtual scenery over time, e.g., the movement of road users in a road traffic scenery. The image of the scenery, and consequently also the synthetic camera data, then represent a momentary state of the virtual scenery in each run, the momentary state including in particular momentary locations, spatial orientations, or poses of objects in the virtual scenery.

Solving the integrals requires the greatest computational effort in deriving the scaling factors according to equation (3). However, since these are neither location- nor time-dependent, it is sufficient to calculate them once. For each surface element to which one or more base functions are assigned, the integrals to be solved to derive the scaling factors can be pre-calculated, and the scene simulation can be started after the pre-calculation is completed. The remaining computational effort required to determine the scaling factors c₁, . . . , cₘ after solving the integrals in equation (3) is so low that it can easily be carried out in real time.

If the surface element is in the form of a passive emitter, it is advantageous that at least the first base function B₁ (without loss of generality) takes into account a spectral distribution of an illumination of the surface element and a reflection spectrum of the surface element. The spectral distribution of the illumination may optionally be configured as a standard illuminant, for example a standard illuminant of type A (incandescent lamp), D65 (standard daylight), F1 to F6 (fluorescent tube, different types), and LED-RGB1 (white LED light). The reflection spectrum can be assigned, in particular, to a material attribute, which in turn is assigned or assignable to the surface element. A software tool for creating the virtual scenery may include, for example, a materials database containing a plurality of different material attributes that can be assigned to different surface elements in the virtual scenery. A material-specific reflection spectrum is assigned to each material attribute in the database, and the respectively assigned reflection spectrum is automatically assigned to the surface element through the assignment of a material attribute to a surface element.

The color space coordinates k₁, . . . , kₙ are preferably calculated taking into account a spatial orientation of the surface element in relation to the simulated camera, i.e., taking into account an angle between an optical axis of the camera and a surface normal of the surface element. Such an angular dependence is known to those skilled in the art as a bi-directional reflection distribution function. Its consideration in the calculation of color space coordinates of a surface element is natively integrated in many graphics engines. The use of angle-dependent color space coordinates in the context of an exemplary embodiment of the inventive method results in an angle-dependent spectral simulation, which, in the prior art, can only be performed with high computational effort and not in real time.

The method is also suitable for simulating infrared cameras or ultraviolet cameras, which operate completely or partially outside the visible spectral range, i.e., below 380 nanometers or above 780 nanometers. For this purpose, the spectral radiance is calculated such that it includes the desired wavelengths outside of the visible spectral range, for example by suitably selecting the integration limits λ₁, λ₂ in equation (3).

The camera data calculated using the method is preferably in the form of camera raw data, which refers to the unprocessed data that is directly output from the image sensor of the camera. Normally, the camera raw data is a matrix of electrical quantities (voltage, current, or charge), each of which reflects an exposure of an image sensor pixel. The electrical response of a single image sensor pixel results from the spectrum of the light illuminating the pixel and the quantum efficiency of the pixel. Quantum efficiency is a wavelength-dependent responsivity of the pixel. Taking into account at least one quantum efficiency of a simulated image sensor of the simulated camera, e.g., a uniform quantum efficiency over all simulated sensor pixels, camera raw data can therefore be directly calculated from the calculated spectral density or from a plurality of spectral densities calculated using an exemplary embodiment of the inventive method.

The synthetic camera data is preferably read and processed by at least one component of an electronic system configured for processing the camera data. In this case, an interface is provided for providing the camera data, so that the at least one component can read it. The component or the electronic system may be a test object whose response to the camera data is to be evaluated. Instead of providing the synthetic camera data for evaluation purposes, it may also be provided for training the electronic system, in particular a neural network of the electronic system. The electronic system may in particular be an electronic system under development. The component may include the entire electronic system or any substructure of the electronic system, such as a subsystem, an assembly, an electronic element, a component, a single processor, a single FPGA (Field Programmable Gate Array), or a comparable component for implementing hard-wired program logic, software, or a software component.

Due to its suitability for simulating infrared cameras, the method is particularly suitable for evaluating or training an assistance system designed to evaluate camera data from a camera directed at a person in order to monitor the state of the person. The person may in particular be a person operating a vehicle or a machine. Such assistance systems often operate in the infrared range. This allows them to function even in the dark, making it possible to illuminate the person with infrared light without blinding him or her. In this case, the virtual scenery (also referred to as a virtual scene) includes a virtual representation of the person, and the image of the virtual scenery therefore includes an image of the person. Accordingly, the spectral distribution of the illumination may simulate an infrared (or possibly also ultraviolet) illumination of the operating person.

Aspects of the present invention also relate to a computer program product storing instructions for performing a method according to the invention. Aspects of the invention also relate to a computer system configured for calculating synthetic camera data according to an exemplary embodiment of the inventive method, and furthermore, an interface for providing the synthetic camera data for reading and processing by at least one component of an electronic system configured for processing the camera data.

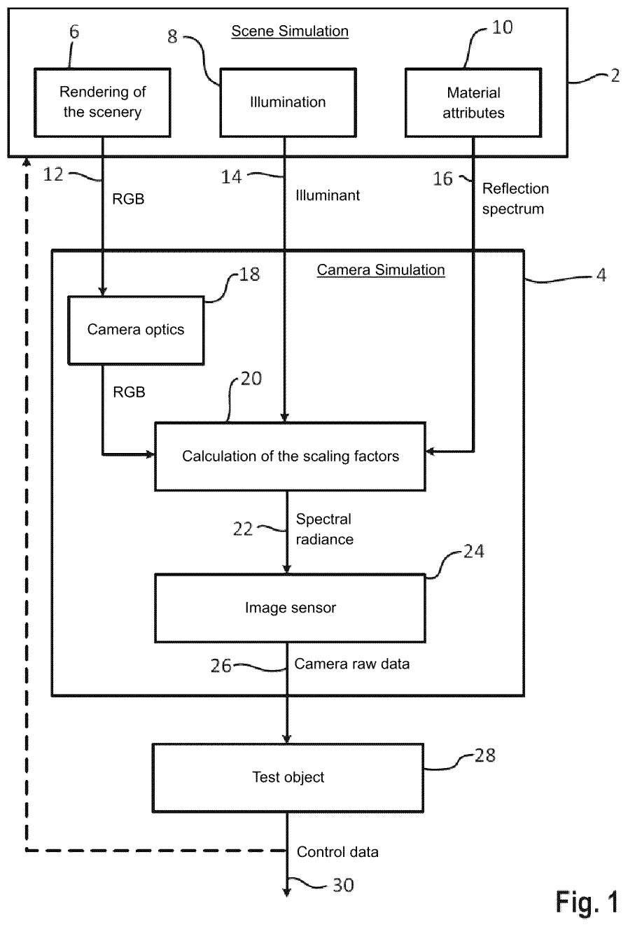

As illustrated in the diagram of FIG. 1, a computer system for implementing one ore more embodiments of the invention typically includes three components: a scene simulation 2, a camera simulation 4, and a test object 28.

The scene simulation includes a rendering 6 of scenery 42. Rendering 6 is done using a graphics engine, such as is commercially available from various vendors, such as, for example, the Unreal Engine from Epic Games, Inc. Scenery 42 is a 3D scenery filled with a plurality of static and moving graphical objects. The configuration of scenery 42 is dependent on test object 28 and on the test requirements. As a general principle, scenery 42 should include the aspects that are essential for the intended use of test object 28, which is provided for detecting and assessing such aspects. For example, if test object 28 is provided as part of a pedestrian detection system of a highly automated automobile, scenery 42 should be configured as a road traffic scenery containing virtual pedestrians. If test object 28 is a surveillance camera for automatic detection of drowning accidents, scenery 42 should represent a body of water with virtual swimmers, some of which show a behavior typical of a swimmer in distress.

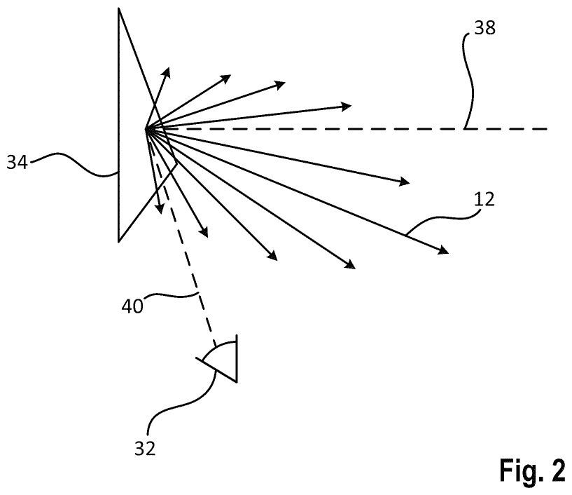

The diagram of FIG. 2 illustrates the method step of rendering 6. The graphics engine renders scenery 42 using an sRGB color space that is optimized for displaying scenery 42 on a monitor such that it appears realistic to the human eye. Scenery 42 is composed of a large number of textured polygons 34 forming the elementary surface elements of the surfaces visible in scenery 42. The graphics engine renders scenery 42 from the perspective of a virtual camera 32 and stores, for rendering 6, color information in the form of an RGB vector 12 for each surface element 34 visible to virtual camera 32. An RGB vector 12 contains three color space coordinates for the red, green, and blue color values. However, the values of the three coordinates depend on the spatial orientation of surface element 34 in relation to virtual camera 32, i.e., on a solid angle between the straight line 40 connecting virtual camera 32 to surface element 34 and the surface normal 38 of surface element 34. In addition, in the case of a reflective surface element 34, there is a dependence on the position of the light source. In the drawing, this dependence is represented by different magnitudes of the RGB vectors 12 in different spatial directions. In this way, the graphics engine simulates a directional dependence of the electromagnetic radiation coming from surface element 34.

Referring back to FIG. 1, scene simulation 2 further includes an illumination 8 and material attributes 10, both of which are additional information that complements the scenery 42 rendered by the graphics engine, but is not natively provided by the graphics engine. Illumination 8 includes at least one illuminant 14, i.e., an electromagnetic spectrum of an ambient light illuminating surface element 34. Illumination 8 may include several electromagnetic spectra when surface element 34 in scenery 42 is illuminated by several different light sources 46. Each electromagnetic spectrum stored in illumination 8 can be stored as an analytical expression or as a lookup table, it being advantageous to store it as a lookup table of sufficiently fine resolution.

Material attributes 10 are a materials database containing a plurality of materials, and each material can be assigned as an attribute to a given surface element 34. A reflection spectrum S (reference numeral 16) is assigned to each of a plurality of material attributes 10 and stored in the materials database. A reflection spectrum 16 is a material-specific, wavelength-dependent reflectivity, which indicates, for a spectrum of wavelengths, the portion of an incident light intensity of the respective wavelength that is reflected by the material.

Assuming, for example, that surface element 34 is a part of the face of an automobile driver 44 rendered by the graphics engine, then, depending on the desired skin color of automobile driver 44, a material attribute “human skin (medium light),” for example, may be assigned to surface element 34, and, as a result of such assignment, a reflection spectrum 16 that simulates the reflection spectrum of human skin of the corresponding skin color as measured in reality. The reflection spectra 16 assigned to material attributes 10 are solely wavelength-dependent. They do not take into account any angular dependence of the reflection.

Camera simulation 4 is also not a native component of the graphics engine, but complements it. It should not be confused with virtual camera 32. The latter only determines the image rendered by the graphics engine, while camera simulation 4 emulates the data pipeline of a real camera. However, the camera simulated by camera simulation 4 is identical to virtual camera 32 in terms of its position and spatial orientation in virtual scenery 42, so that the rendering 6 of the graphics engine can be used by camera simulation 4 for further processing. The two may also overlap in the technical process, so that native algorithms of virtual camera 32 are used directly for camera simulation 4, or that algorithms of camera simulation 4 are integrated into native algorithms of virtual camera 32. The main distinguishing feature is that virtual camera 32 of the graphics engine renders an RGB image (more generally: a multi-stimulus image) of virtual scenery 42 from the perspective of virtual camera 32, which image is displayable on a monitor, while camera simulation 4 generates camera data based on the virtual scenery from the same perspective.

Camera simulation 4 reads the RGB vectors 12 with the color space coordinates stored by the graphics engine and assigned to the surface elements 34 and processes them in a camera optics simulation 18. Camera optics simulation 18 simulates the process in which the light entering the camera from the virtual scenery is imaged onto the sensor pixels of an image sensor of the simulated camera. As a result of camera optics simulation 18, an RGB vector 12 for the light illuminating a simulated sensor pixel is present for each simulated sensor pixel. Then, an electromagnetic spectrum is calculated from each of these RGB vectors 12 using equation (3).

A calculation routine 20 for scaling factors c₁, . . . , cₘ, which is executed for each sensor pixel, reads the RGB vector 12 of the respective sensor pixel from camera optics simulation 18. Calculation routine 20 reads, from illumination 8, one or more illuminants 14 of the surface element 34 that is imaged on the respective sensor pixel. Calculation routine 20 reads, from material attributes 10, the reflection spectrum 16 assigned to the surface element 34 that is imaged on the respective sensor pixel.

For the exemplary embodiment described here, test object 28 is assumed to be a driver assistance system for monitoring an automobile driver 44. The driver assistance system is intended to monitor the driver's attentiveness and ability to drive based on measurable criteria, such as gaze direction, head pose, yawning, or eye blink frequency, and, if necessary, to output control data for a periphery of assistance system in order to trigger a vehicle response, such as a wake-up signal, a request to stop for a rest, an emergency call, a change to an autonomous driving mode, or an emergency braking maneuver.

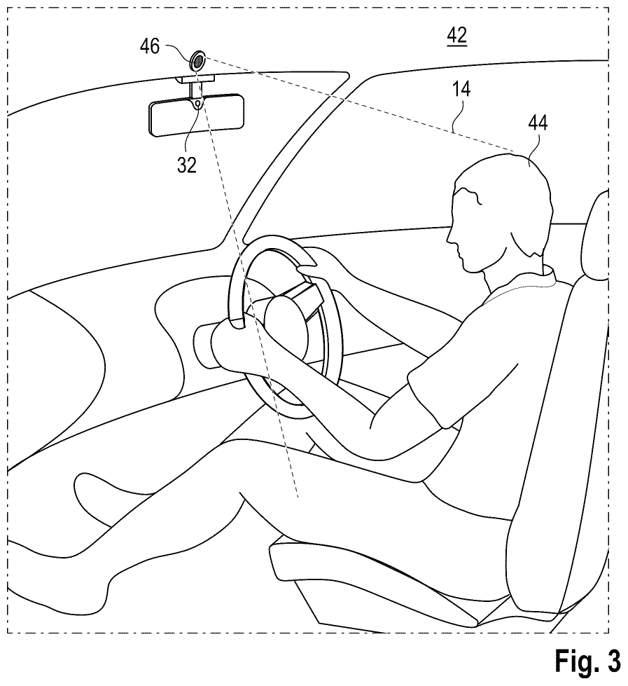

FIG. 3 sketches a virtual scenery 42 set up for a test or training of this assistance system. Virtual Scenery 42 includes a passenger compartment of a vehicle with a driver 44.

The scenery evolves over time: The graphical model of driver 44 moves and can realistically simulate behaviors that are relevant in particular for test object 28, such as yawning, averting the eyes from the road, microsleep, influence of drugs or alcohol, or medical emergencies such as a heart attack, stroke, or shock. Virtual camera 32 is positioned on the front of the interior rearview mirror and simulates a cabin camera directed at driver 44 to monitor driver 44. The simulated cabin camera detects an electromagnetic spectrum of the wavelength range λ=[650 nm, 1100 nm], i.e., it operates partly in the near-infrared range.

Virtual scenery 42 also includes an infrared lamp 46 to illuminate 14 driver 44 in a manner invisible to the human eye. The electromagnetic spectrum of the infrared lamp is stored in illumination 8 as a first illuminant I_{IR}. The daylight entering the vehicle from outside is stored in illumination 8 as a second illuminant I_{D}=D65 (standard daylight according to the CIE standard colorimetric system).

A reflection spectrum S_{H1} (human skin, medium light) is assigned to the surface element 34 in accordance with material attributes 10. Using the information read, calculation routine 20 in FIG. 1 assigns to surface element 34 a single base function according to equation (1):

$${B}_{1} = ( {wI}_{IR} + {I}_{D} ) {S}_{H 1}$$

with a weighting factor w to determine the relative intensity of infrared illumination compared to daylight. Base function B₁ describes an angle-independent electromagnetic spectrum reflected by surface element 34. For this base function, calculation routine 20 performs the following calculations: the spectral radiance of the light imaged by surface element 34 onto an image sensor pixel is obtained according to equation (1) as

$$L ( λ ) = {c}_{1} ( {wI}_{IR} + {I}_{D} ) {S}_{H 1}$$

and the coefficient c₁ is obtained according to equation (3) as follows:

$$r = {c}_{1} {R}_{1} {\int }_{{λ}_{1} = 650 nm}^{{λ}_{2} = 1100 nm} ( {wI}_{IR} ( λ ) + {I}_{D} ( λ ) ) {S}_{H 1} ( λ ) \overline{r} d λ$$

All variables occurring in the integral are already known before the start of scene simulation 2, and the number of base functions to be potentially processed by calculation routine 20 is finite, provided that the number of reflection spectra 16 stored in material attributes 14 and the number of illuminants 10 stored in illumination 8 are finite. Consequently, all integrals potentially to be arithmetically combined by calculation routine 20, i.e., the integrals resulting from all possible combinations of illuminants and reflection spectra, can already be pre-calculated before the start of scene simulation 2 and stored in a memory for reading by calculation routine 20. The calculation of spectral radiance 22 by determining c₁ can then be performed in real time without difficulty. Color space coordinate r is stored in RGB vector 12 and is supplied by the graphics engine in an angle-dependent manner. As a result, c₁ and ultimately spectral radiance L(α) are angle-dependent, too. Thus, the method enables real-time-capable, angle-dependent spectral camera simulation using the RGB pipeline natively present in the graphics engine. Further base functions can optionally be assigned to the surface element, for example as a correction term or to account for a radiation spectrum actively emitted by surface element 34 if surface element 34 belongs to an active radiator within virtual scenery 42.

The calculation can optionally be repeated for the remaining two color space coordinates g and b. In this way, three independent values are obtained for c₁, which are likely to differ slightly from each other because they are calculated independently of each other, which makes it possible to perform error minimization. For example, it is possible to select, from the value interval obtained for c₁, the value for which the vector (r, g, b) calculated on the basis of the value has the smallest deviation from the vector supplied by the graphics engine.

Spectral radiance L (reference numeral 22) is read by an image sensor simulation 24 which, using the spectral radiance L calculated for a given sensor pixel and a wavelength-dependent quantum efficiency q of the sensor pixel, calculates the electrical response of the sensor pixel and, as the totality of the electrical responses of all sensor pixels, camera raw data 26. In the simplest case, the electrical response R_{E} of a sensor pixel is obtained by the equation

$${R}_{E} = K {\int }_{{λ}_{1}}^{{λ}_{2}} L ( λ ) q ( λ ) d λ = K {c}_{1} {\int }_{{λ}_{1}}^{{λ}_{2}} ( {wI}_{IR} ( λ ) + {I}_{D} ( λ ) ) {S}_{H 1} ( λ ) q ( λ ) d λ$$

This integral, too, depends solely on the wavelength and, in analogy to the integrals in equation (3), is therefore pre-calculated before the start of the scene simulation and stored in a memory for reading by image sensor simulation 24. K is a variable scaling factor that is used in particular to take into account the exposure time of the simulated camera.

The synthetic camera raw data 26 is finally stored via a suitable interface provided for this purpose for reading by test object 28. Test object 28 processes camera raw data 26 in the same way as it would do in a real working environment with real camera raw data, and, as a result of such processing, outputs control data 30 in response to synthetic camera raw data 26. On the basis of control data 30, a person skilled in the art can evaluate the behavior of test object 28 by matching the response of the test object to synthetic camera raw data 30 with a desired response.

Control data 30 may optionally be provided for reading by scene simulation 2 (as indicated by a dashed arrow), so that it can take the control data into account in scene simulation 2. For example, the scene simulation 2 may respond to a wake-up signal requested based on control data 30 with a corresponding animation of driver 44, re-opening the closed eyes of driver 44 and returning his/her head to an upright position.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method for generating synthetic camera data, the method comprising:
rendering, by a computer system, an image of a virtual scene and storing color information of a surface element of the virtual scene in the form of color space coordinates of a multi-stimulus color space;
assigning, by the computer system, to the surface element, a number of base functions which each describe a relative wavelength distribution of a light component emitted from the surface element;
modeling, by the computer system, a spectral radiance of the light emitted from the surface element as a linear combination of the base functions;
deriving, by the computer system, scaling factors of the base functions in the linear combination by arithmetically combining the spectral radiance with a color space coordinate from the color information of the surface element and a color matching function associated with the color space coordinate;
calculating, by the computer system, the spectral radiance by inserting the scaling factors; and
generating, by the computer system, the synthetic camera data by processing the spectral radiance in a camera simulation of a camera located in the virtual scene.

2. The method according to claim 1, wherein one of the base functions takes into account a spectral distribution of an illumination of the surface element and a reflection spectrum of the surface element.

3. The method according to claim 2, wherein a material attribute is assigned to the surface element, and the reflection spectrum is assigned to the material attribute.

4. The method according to claim 1, further comprising:
pre-calculating integrals to be solved to derive the scaling factors; and
starting a scene simulation of an evolution of the virtual scene over time after completion of the pre-calculation of the integrals, the scene simulation including a repetition of the rendering, the assigning, the modeling, the deriving, the calculating, and the generating;
wherein, in each cycle, the image of the virtual scene depicts a current state of the virtual scene, and the synthetic camera data is generated in each cycle using the pre-calculated integrals.

5. The method according to claim 1, further comprising:
calculating the color space coordinates taking into account a spatial orientation of the surface element in relation to the camera.

6. The method according to claim 5, wherein calculating the color space coordinates takes into account an angle between a straight line connecting the camera to the surface element and a surface normal of the surface element.

7. The method according to claim 1, wherein the spectral radiance is calculated in such a way that the spectral radiance includes wavelengths outside the visible spectral range.

8. The method according to claim 7, wherein the spectral radiance includes wavelengths below 380 nanometers or above 780 nanometers.

9. The method according to claim 1, wherein the synthetic camera data is generated as synthetic camera raw data, taking into account a quantum efficiency of a simulated image sensor of the camera.

10. The method according to claim 1, further comprising:
reading and processing, by a component of an electronic system configured for processing the camera data, the synthetic camera data for training the electronic system or for evaluating a response of the electronic system to the synthetic camera data.

11. The method according to claim 10, wherein the spectral radiance is calculated in such a way that the spectral radiance includes wavelengths outside the visible spectral range;
wherein the electronic system is an assistance system configured to analyze camera data from a camera directed at a person in order to monitor state of the person, the camera being capable of detecting wavelengths outside the visible spectral range; and
wherein the virtual scene includes a virtual representation of the person, and the image of the virtual scene includes an image of the person.

12. The method according to claim 11, wherein the camera is directed at the person while the person is operating a vehicle or a machine.

13. The method according to claim 11, wherein one of the base functions takes into account a spectral distribution of an illumination of the surface element and a reflection spectrum of the surface element; and
wherein the spectral distribution of the illumination simulates an infrared or ultraviolet illumination of the operating person.

14. A non-transitory computer-readable medium having processor-executable instructions stored thereon for generating synthetic camera data, wherein the processor-executable instructions, when executed, facilitate performance of the following by a computer system:
rendering an image of a virtual scene and storing color information of a surface element of the virtual scene in the form of color space coordinates of a multi-stimulus color space;
assigning, to the surface element, a number of base functions which each describe a relative wavelength distribution of a light component emitted from the surface element;
modeling a spectral radiance of the light emitted from the surface element as a linear combination of the base functions;
deriving scaling factors of the base functions in the linear combination by arithmetically combining the spectral radiance with a color space coordinate from the color information of the surface element and a color matching function associated with the color space coordinate;
calculating the spectral radiance by inserting the scaling factors; and
generating the synthetic camera data by processing the spectral radiance in a camera simulation of a camera located in the virtual scene.

15. A computer system, comprising:
at least one processor configured to:
render an image of a virtual scene and storing color information of a surface element of the virtual scene in the form of color space coordinates of a multi-stimulus color space;
assign, to the surface element, a number of base functions which each describe a relative wavelength distribution of a light component emitted from the surface element;
model a spectral radiance of the light emitted from the surface element as a linear combination of the base functions;
derive scaling factors of the base functions in the linear combination by arithmetically combining the spectral radiance with a color space coordinate from the color information of the surface element and a color matching function associated with the color space coordinate;
calculate the spectral radiance by inserting the scaling factors; and
generate the synthetic camera data by processing the spectral radiance in a camera simulation of a camera located in the virtual scene; and
an interface configured to provide the generated synthetic camera data to at least one component of an electronic system configured for processing camera data.
